(19) United States
(12) Patent Application Publication
(10) Pub. No.: US 2021/0180185 A1
(43) Pub. Date: Jun. 17, 2021

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Daisuke HARA, Toyama-shi (JP); Takashi YAHATA, Toyama-shi (JP); Tsuyoshi TAKEDA, Toyama-shi (JP)

(73) Assignee: KOKUSAI ELECTRIC CORPORATION, Tokyo (JP)

(21) Appl. No.: 17/186,498

(22) Filed: Feb. 26, 2021

Related U.S. Application Data
(63) Continuation of application No. PCT/JP2018/033627, filed on Sep. 11, 2018.

(51) Int. Cl. C23C 16/44; H01L 21/02; H01J 37/32; C23C 16/455

(52) U.S. Cl. CPC C23C 16/4408; H01L 21/0217; H01L 21/02274; H01J 2237/3322; H01J 37/32449; C23C 16/45574; H01J 37/32853

(57) ABSTRACT

There is provided a technique that includes: a substrate support configured to support at least one substrate; a reaction tube configured to accommodate the at least one substrate support and process the at least one substrate; and an inert gas supply system configured to supply an inert gas into the reaction tube, wherein the inert gas supply system includes a nozzle including at least one first ejection hole configured to eject the inert gas toward a center of the at least one substrate and at least one second ejection hole configured to eject the inert gas toward an inner wall of the reaction tube.

### CROSS-REFERENCE TO RELATED APPLICATION

This application is a Bypass Continuation Application of PCT International Application No. PCT/JP2018/033627, filed Sep. 11, 2018, the disclosure of which is incorporated herein in its entirety by reference.

### TECHNICAL FIELD

The present disclosure relates to a substrate processing apparatus, a method of manufacturing a semiconductor device, and a recording medium.

### BACKGROUND

In the related art, as a process of manufacturing a semiconductor device, a process gas may be supplied to a substrate accommodated in a reaction tube to perform a process (for example, a film-forming process) on the substrate. At this time, when reaction by-products adhere to an inner wall of the reaction tube, foreign substances (particles) are generated due to the reaction by-products, which deteriorates a quality of the process on the substrate.

### SUMMARY

Some embodiments of the present disclosure provide a technique capable of preventing generation of deposits on an inner wall of a reaction tube.

According to some embodiments of the present disclosure, there is provided a technique that includes: a substrate support configured to support at least one substrate; a reaction tube configured to accommodate the at least one substrate support and process the at least one substrate; and an inert gas supply system configured to supply an inert gas into the reaction tube, wherein the inert gas supply system includes a nozzle including at least one first ejection hole configured to eject the inert gas toward a center of the at least one substrate and at least one second ejection hole configured to eject the inert gas toward an inner wall of the reaction tube.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing apparatus suitably used in some embodiments of the present disclosure, in which a portion of the process furnace is illustrated in a vertical cross-sectional view.

FIG. 2 is a schematic configuration view of the vertical process furnace of the substrate processing apparatus suitably used in some embodiments of the present disclosure, in which a portion of the process furnace is illustrated in a cross-sectional view taken along a line A-A in FIG. 1.

FIG. 3 is a schematic configuration view of a nozzle structure of a substrate processing apparatus suitably used in some embodiments of the present disclosure, in which a portion of the nozzle structure is illustrated in a vertical cross-sectional view.

FIGS. 4A and 4B are schematic configuration views of a buffer structure of a substrate processing apparatus suitably used in some embodiments of the present disclosure, in which FIG. 4A is an enlarged horizontal cross-sectional view for explaining the buffer structure, and FIG. 4B is a schematic view for explaining the buffer structure.

FIG. 5 is a schematic configuration diagram of a controller of the substrate processing apparatus suitably used in some embodiments of the present disclosure, in which a control system of the controller is illustrated in a block diagram.

FIG. 6 is a flowchart of a substrate processing process according to some embodiments of the present disclosure.

FIG. 7 is a diagram showing gas supply timings in the substrate processing process according to some embodiments of the present disclosure.

FIGS. 8A and 8B are schematic configuration views for explaining a first modification of a nozzle structure of a substrate processing apparatus suitably used in some embodiments of the present disclosure, in which FIG. 8A is an enlarged horizontal cross-sectional view of a portion of the nozzle structure, and FIG. 8B is an enlarged horizontal cross-sectional view of a portion of a gas supply hole in a nozzle.

FIG. 9 is a schematic configuration view for explaining a second modification of a nozzle structure of a substrate processing apparatus suitably used in some embodiments of the present disclosure, in which a portion of the nozzle structure is illustrated in a vertical cross-sectional view.

FIG. 10 is a schematic configuration view for explaining a third modification of a nozzle structure of a substrate processing apparatus suitably used in some embodiments of the present disclosure, in which a portion of the nozzle structure is illustrated in a horizontal cross-sectional view.

### DETAILED DESCRIPTION

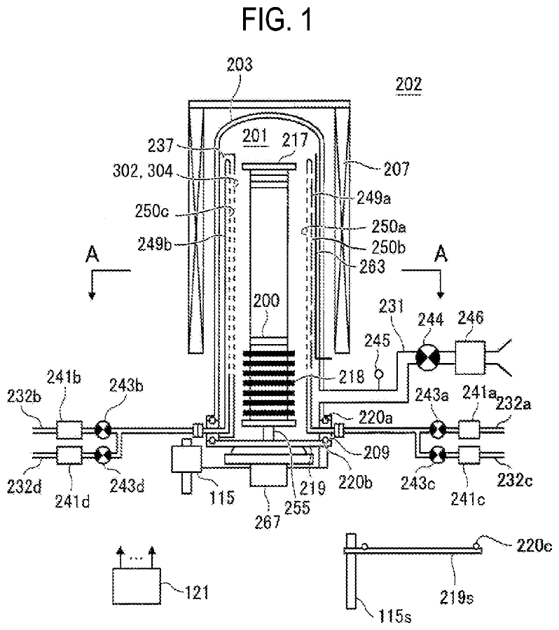

Embodiments of the present disclosure will be now described with reference to FIGS. 1 to 7.

### (1) Configuration of Substrate Processing Apparatus (Heating Device)

As illustrated in FIG. 1, a process furnace 202 is a so-called vertical furnace in which substrates can be accommodated in multiple stages in a vertical direction, and includes a heater 207 as a heating device (a heating mechanism). The heater 207 has a cylindrical shape and is supported by a heater base (not shown) serving as a holding plate to be vertically installed. As will be described later, the heater 207 also functions as an activation mechanism (an excitation part) configured to thermally activate (excite) a gas.

### (Process Chamber)

A reaction tube 203 is disposed inside the heater 207 to be concentric with the heater 207. The reaction tube 203 is made of, for example, a heat resistant material such as quartz (SiO₂), silicon carbide (SiC) or silicon nitride (SiN) and is formed in a cylindrical shape with its upper end closed and its lower end opened. A manifold (inlet flange) 209 is disposed under the reaction tube 203 to be concentric with the reaction tube 203. The manifold 209 is made of, for example, metal such as stainless steel (SUS: Steel Use Stainless) and is formed in a cylindrical shape with both of its upper and lower ends opened. The upper end portion of the manifold 209 engages with the lower end portion of the reaction tube 203 to support the reaction tube 203. An O-ring 220a serving as a seal member is installed between the manifold 209 and the reaction tube 203. As the manifold 209 is supported by the heater base, the reaction tube 203 is in a state of being vertically installed. A process container (reaction container) mainly includes the reaction tube 203 and the manifold 209. A process chamber 201 is formed in a hollow cylindrical portion which is the inside of the process container. The process chamber 201 is configured to be capable of accommodating a plurality of wafers 200 as substrates. Note that the process container is not limited to the above configuration, and only the reaction tube 203 may be referred to as the process container.

Nozzles 249a and 249b are installed in the process chamber 201 to penetrate a sidewall of the manifold 209. Gas supply pipes 232a and 232b are connected to the nozzles 249a and 249b, respectively. In this way, the two nozzles 249a and 249b and the two gas supply pipes 232a and 232b are installed at the reaction tube 203, thereby allowing plural types of gases to be supplied into the process chamber 201.

Mass flow controllers (MFCs) 241a and 241b, which are flow rate controllers (flow rate control parts), and valves 243a and 243b, which are opening/closing valves, are installed at the gas supply pipes 232a and 232b, respectively, sequentially from the corresponding upstream sides of a gas flow. Gas supply pipes 232c and 232d configured to supply an inert gas are connected to the gas supply pipes 232a and 232b at downstream sides of the valves 243a and 243b, respectively. MFCs 241c and 241d and valves 243c and 243d are installed at the gas supply pipes 232c and 232d, respectively, sequentially from the corresponding upstream sides of a gas flow.

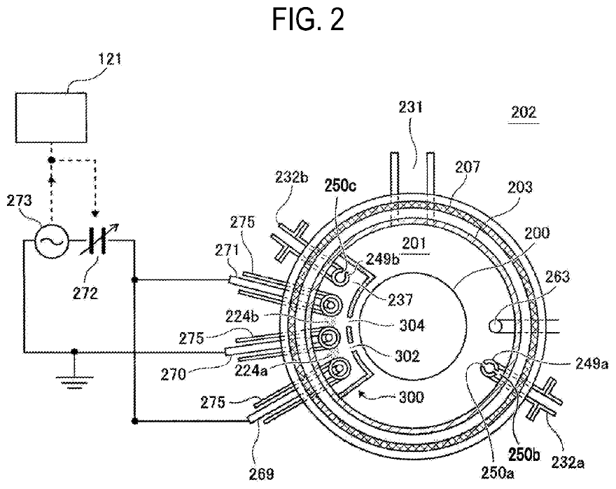

As illustrated in FIG. 2, the nozzle 249a is installed in a space between an inner wall of the reaction tube 203 and the wafers 200 to extend upward along a stack direction of the wafers 200 from a lower portion to an upper portion of the inner wall of the reaction tube 203. Specifically, the nozzle 249a is installed in a region horizontally surrounding a wafer arrangement region (mounting region) in which the wafers 200 are arranged (mounted) at a lateral side of the wafer arrangement region, along the wafer arrangement region. That is, the nozzle 249a is installed in a perpendicular relationship with the surfaces (flat surfaces) of the wafers 200 at a lateral side of end portions (peripheral portions) of the respective wafers 200 loaded into the process chamber 201.

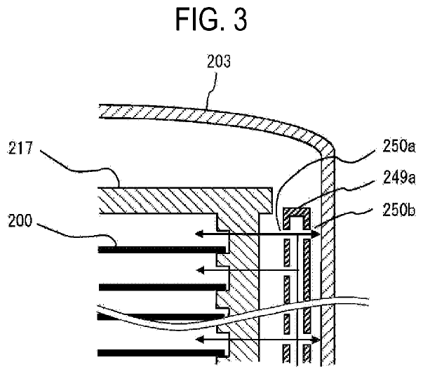

As illustrated in FIGS. 2 and 3, as gas supply holes configured to supply a gas, a first ejection hole 250a and a second ejection hole 250b are formed on the side surface of the nozzle 249a.

The first ejection hole 250a is opened toward a center of the reaction tube 203 (the wafers 200) to allow a gas (particularly an inert gas) to be supplied (ejected) to the wafers 200. That is, the first ejection hole 250a is formed on one side surface of the nozzle 249a to eject the inert gas or the like toward the centers of the wafers 200.

The second ejection hole 250b is opened toward the inner wall of the reaction tube 203 to allow a gas (particularly an inert gas) to be supplied (ejected) to the inner wall of the reaction tube 203. That is, the second ejection hole 250b is formed on the other side surface of the nozzle 249a (a surface facing the first ejection hole 250a) to eject the inert gas or the like to the inner wall of the reaction tube 203.

In this way, the first ejection hole 250a configured to eject the inert gas or the like toward the center of the wafers 200 and the second ejection hole 250b configured to eject the inert gas or the like toward the inner wall of the reaction tube 203 are formed at positions opposite to each other in the nozzle 249a.

A plurality of first ejection holes 250a and a plurality of second ejection holes 250b are formed from the lower portion to the upper portion of the reaction tube 203. Specifically, the plurality of first ejection holes 250a are formed from the lower portion to the upper portion of the reaction tube 203 along a height direction of the nozzle 249a. The first ejection holes 250a are formed to have the same opening area at first predetermined intervals. Further, the plurality of second ejection holes 250b are formed from the lower portion to the upper portion of the reaction tube 203 along the height direction of the nozzle 249a. The second ejection holes 250b are formed to have the same opening area at second predetermined intervals, each of which is wider than each of the first predetermined intervals. That is, the plurality of first ejection holes 250a are formed at the first predetermined intervals with respect to the height direction of the nozzle 249a, and the plurality of second ejection holes 250b are formed at the second predetermined intervals, each of which is wider than each of the first predetermined intervals, with respect to the height direction of the nozzle 249a.

Since the second predetermined interval is wider than the first predetermined interval, the number of first ejection holes 250a is larger than the number of the second ejection holes 250b. Specifically, the first ejection holes 250a and the second ejection holes 250b are formed at, for example, a ratio of 2.5:1 in number. Further, it is assumed that an opening diameter of the first ejection holes 250a is larger than an opening diameter of the second ejection holes 250b. Specifically, the opening diameter of the first ejection holes 250a and the opening diameter of the second ejection holes 250b are formed, for example, at a ratio of 2:1. Further, each of the ratios given here is merely a specific example, but the present disclosure is not limited thereto. Further, shapes of openings of the first ejection holes 250a and shapes of openings of the second ejection holes 250b may be circular but are not limited thereto. For example, these holes 250a and 250b may have another shape such as an elliptical shape.

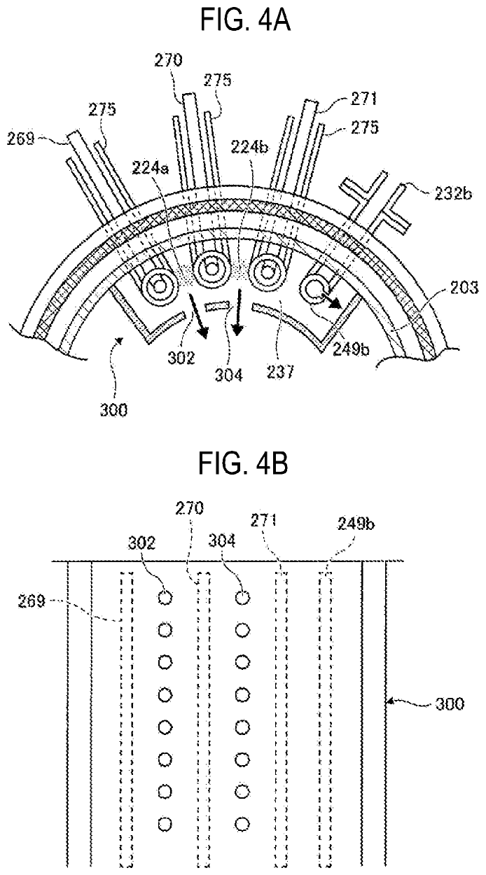

As illustrated in FIGS. 1 and 2, the nozzle 249b is connected to a leading end of the gas supply pipe 232b. The nozzle 249b is disposed in a buffer chamber 237 serving as a gas dispersion space. As illustrated in FIG. 2, the buffer chamber 237 is disposed in an annular space, in a plane view), between the inner wall of the reaction tube 203 and the wafers 200, along the stack direction of the wafers 200 from the lower portion to the upper portion of the inner wall of the reaction tube 203. That is, the buffer chamber 237 is formed by a buffer structure 300 along the wafer arrangement region in a region horizontally surrounding the wafer arrangement region at the lateral side of the wafer arrangement region. The buffer structure 300 is made of insulating material such as quartz. Gas supply ports 302 and 304 configured to supply a gas are formed on an arc-shaped wall surface of the buffer structure 300. As illustrated in FIGS. 2, 4A and 4B, the gas supply ports 302 and 304 are respectively opened toward the center of the reaction tube 203 at positions opposite to plasma generation regions 224a and 224b between rod-shaped electrodes 269 and 270 to be described below and between rod-shaped electrodes 270 and 271 to be described below, thereby allowing a gas to be supplied toward the wafers 200. A plurality of gas supply ports 302 and 304 may be formed to have the same opening area at the same opening pitch between the lower portion and the upper portion of the reaction tube 203.

The nozzle 249b is installed to extend upward along the stack direction of the wafers 200 from the lower portion to the upper portion of the inner wall of the reaction tube 203. Specifically, the nozzle 249b is installed in a region horizontally surrounding the wafer arrangement region in which the wafers 200 are arranged at the lateral side of the wafer arrangement region inside the buffer structure 300, along the wafer arrangement region. That is, the nozzle 249b is installed in a perpendicular relationship with the surfaces of the wafers 200 at the lateral side of the end portions of the wafers 200 loaded into the process chamber 201. A gas supply hole 250c configured to supply a gas is formed on the side surface of the nozzle 249b. The gas supply hole 250c is opened toward a wall surface formed in the radial direction with respect to the arc-shaped wall surface of the buffer structure 300, thereby allowing a gas to be supplied toward the wall surface. As a result, a reaction gas is dispersed in the buffer chamber 237 and is not directly ejected to the rod-shaped electrodes 269 to 271, thereby suppressing generation of particles. As with the first ejection holes 250a, a plurality of gas supply holes 250c are formed between the lower portion and the upper portion of the reaction tube 203.

In this way, in the embodiments, a gas is transferred via the nozzles 249a and 249b and the buffer chamber 237 arranged in an annular longitudinal space, that is, a cylindrical space, in the plane view, defined by the inner wall of the side wall of the reaction tube 203 and the ends of the plurality of wafers 200 arranged in the reaction tube 203. Then, the gas is ejected into the reaction tube 203 near the wafers 200 for the first time from the first ejection holes 250a, the second ejection holes 250b, and gas supply holes 250c formed in the nozzles 249a and 249b and the gas supply ports 302 and 304 formed in the buffer chamber 237. The main flow of the gas in the reaction tube 203 is in a direction parallel to the surfaces of the wafers 200, that is, in a horizontal direction. With such a configuration, the gas can be uniformly supplied to each wafer 200, so that uniformity of film thickness formed on each wafer 200 can be improved. A gas flowing on the surfaces of the wafers 200, that is, the residual gas after reaction flows toward an exhaust port, that is, an exhaust pipe 231 to be described below. However, a direction of the flow of the residual gas is appropriately specified depending on the position of the exhaust port, and is not limited to the vertical direction.

A precursor containing a predetermined element, for example, a silane precursor gas containing silicon (Si) as the predetermined element, is supplied from the gas supply pipe 232a into the process chamber 201 via the MFC 241a, the valve 243a, and the nozzle 249a.

A precursor gas refers to a gaseous precursor, for example, a gas obtained by vaporizing a precursor in a liquefied state at normal temperature and normal pressure, a precursor in a gaseous state at normal temperature and normal pressure, and the like. When the term “precursor” is used herein, it may indicate a case of including a “liquid precursor in a liquefied state,” a case of including a “precursor gas in a gaseous state,” or a case of including both of them.

An example of the silane precursor gas may include a precursor gas containing Si and a halogen element, that is, a halosilane precursor gas. The halosilane precursor is a silane precursor having a halogen group. The halogen element includes at least one selected from the group of chlorine (Cl), fluorine (F), bromine (Br), and iodine (I). That is, the halosilane precursor contains at least one halogen group selected from the group of a chloro group, a fluoro group, a bromo group, and an iodo group. The halosilane precursor may be said to be a type of halide.

An example of the halosilane precursor gas may include a precursor gas containing Si and Cl, that is, a chlorosilane precursor gas. An example of the chlorosilane precursor gas may include a dichlorosilane (SiH₂Cl₂, abbreviation: DCS) gas.

A reactant containing an element different from the above-mentioned predetermined element, for example, a nitrogen (N)-containing gas as a reaction gas, is supplied from the gas supply pipe 232b into the process chamber 201 via the MFC 241b, the valve 243b, and the nozzle 249b. An example of the N-containing gas may include a hydrogen nitride-based gas. The hydrogen nitride-based gas may be said to be a substance including only two elements of N and H, and acts as a nitriding gas, that is, a N source. An example of the hydrogen nitride-based gas may include an ammonia (NH₃) gas.

An inert gas, for example, a nitrogen (N₂) gas, is supplied from the gas supply pipes 232c and 232d into the process chamber 201 via the MFCs 241c and 241d, the valves 243c and 243d, the gas supply pipes 232a and 232b, and the nozzles 249a and 249b, respectively.

A precursor supply system as a first gas supply system mainly includes the gas supply pipe 232a, the MFC 241a, and the valve 243a. Further, a reactant supply system as a second gas supply system mainly includes the gas supply pipe 232b, the MFC 241b, and the valve 243b. The precursor supply system and the reactant supply system are collectively referred to as a process gas supply system (a process gas supply part). The precursor gas and the reaction gas are collectively referred to as a process gas.

An inert gas supply system mainly includes the gas supply pipes 232c and 232d, the MFCs 241c and 241d, and the valves 243c and 243d. The inert gas supply system may include the nozzle 249a connected to the gas supply pipe 232c via the gas supply pipe 232a. In that case, the inert gas supply system includes the nozzle 249a with the first ejection holes 250a and the second ejection holes 250b.

The precursor supply system, the reactant supply system, and the inert gas supply system described above are also collectively referred to as a gas supply system (a gas supply part).

### (Plasma Generation Part)

As illustrated in FIGS. 2, 4A, and 4B, three rod-shaped electrodes 269, 270, and 271, which are made of a conductor and have an elongated structure, are disposed in the buffer chamber 237 to span from the lower portion to the upper portion of the reaction tube 203 along the stack direction of the wafers 200. Each of the rod-shaped electrodes 269, 270, and 271 is installed parallel to the nozzle 249b. Each of the rod-shaped electrodes 269, 270, and 271 is covered with and protected by an electrode protective tube 275 over a region spanning from an upper portion to a lower portion thereof. Of the rod-shaped electrodes 269, 270, and 271, the rod-shaped electrodes 269 and 271 disposed at both ends are connected to a high frequency power supply 273 via a matching device 272. The rod-shaped electrode 270 is grounded by being connected to the ground that is the reference potential. That is, the rod-shaped electrodes connected to the high frequency power supply 273 and the grounded rod-shaped electrode are alternately arranged. As the grounded rod-shaped electrode, the rod-shaped electrode 270 interposed between the rod-shaped electrodes 269 and 271 connected to the high frequency power supply 273 is used in common for the rod-shaped electrodes 269 and 271. In other words, the grounded rod-shaped electrode 270 is disposed to be sandwiched between the rod-shaped electrodes 269 and 271 connected to the adjacent high frequency power supply 273, and the rod-shaped electrode 269 and the rod-shaped electrode 270, and similarly, the rod-shaped electrode 271 and the rod-shaped electrode 270 are configured to be paired to generate plasma. That is, the grounded rod-shaped electrode 270 is used in common for the rod-shaped electrodes 269 and 271 connected to two high frequency power supplies 273 adjacent to the rod-shaped electrode 270. Then, by applying high frequency (RF) power from the high frequency power supply 273 to the rod-shaped electrodes 269 and 271, plasma is generated in a plasma generation region 224a between the rod-shaped electrodes 269 and 270 and in a plasma generation region 224b between the rod-shaped electrodes 270 and 271. A plasma generation part (a plasma generator) as a plasma source mainly includes the rod-shaped electrodes 269, 270, and 271 and the electrode protective tube 275. The plasma source may include the matching device 272 and the high frequency power supply 273. As described below, the plasma source functions as a plasma excitation part (an activation mechanism) that plasma-excites a gas, that is, excites (activates) a gas into a plasma state.

The electrode protective tube 275 has a structure in which each of the rod-shaped electrodes 269, 270, and 271 can be inserted into the buffer chamber 237 while keeping each of the rod-shaped electrodes 269, 270, and 271 isolated from an internal atmosphere of the buffer chamber 237. In a case where an O₂ concentration within the electrode protective tube 275 is substantially equal to an O₂ concentration in an ambient air (atmosphere), each of the rod-shaped electrodes 269, 270, and 271 inserted into the electrode protective tube 275 may be oxidized by heat generated from the heater 207. For this reason, by charging the interior of the electrode protective tube 275 with an inert gas such as a N₂ gas, or by purging the interior of the electrode protective tube 275 with an inert gas such as a N₂ gas through the use of an inert gas purge mechanism, it is possible to reduce the O₂ concentration within the electrode protective tube 275, thereby preventing oxidation of the rod-shaped electrodes 269, 270, and 271.

### (Exhaust Part)

As illustrated in FIGS. 1 and 2, the exhaust pipe 231 configured to exhaust an internal atmosphere of the process chamber 201 is installed at the reaction tube 203. A vacuum pump 246, as a vacuum-exhausting device, is connected to the exhaust pipe 231 via a pressure sensor 245, which is a pressure detector (pressure detecting part) that detects an internal pressure of the process chamber 201, and an auto pressure controller (APC) valve 244, which is an exhaust valve (pressure regulation part). The APC valve 244 is configured to perform or stop a vacuum-exhausting operation in the process chamber 201 by opening or closing the valve while the vacuum pump 246 is actuated, and is also configured to regulate the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246. The exhaust pipe 231 is not limited to being installed at the reaction pipe 203, but may be installed at the manifold 209 in the same manner as the nozzles 249a and 249b.

A seal cap 219, which serves as a furnace opening lid configured to be capable of hermetically sealing a lower end opening of the manifold 209, is installed under the manifold 209. The seal cap 219 is configured to contact the lower end of the manifold 209 from the lower side in the vertical direction. The seal cap 219 is made of, for example, a metal material such as SUS and is formed in a disc shape. An O-ring 220b, which is a seal member making contact with the lower end of the manifold 209, is installed at an upper surface of the seal cap 219. A rotation mechanism 267 configured to rotate a boat 217 to be described below is installed at the opposite side of the seal cap 219 from the process chamber 201. A rotary shaft 255 of the rotation mechanism 267, which penetrates the seal cap 219, is connected to the boat 217. The rotation mechanism 267 is configured to rotate the wafers 200 by rotating the boat 217. The seal cap 219 is configured to be vertically moved up or down by a boat elevator 115 which is an elevation mechanism vertically installed outside the reaction tube 203. The boat elevator 115 is configured to be capable of loading or unloading the boat 217 into or out of the process chamber 201 by moving the seal cap 219 up or down. The boat elevator 115 is configured as a transfer device (a transfer mechanism) which transfers the boat 217, that is, the wafers 200, into or out of the process chamber 201. Further, a shutter 219s, which serves as a furnace opening lid configured to be capable of hermetically sealing a lower end opening of the manifold 209 while the seal cap 219 is moved down by the boat elevator 115, is installed under the manifold 209. The shutter 219s is made of, for example, a metal material such as SUS and is formed in a disc shape. An O-ring 220c, which is a seal member making contact with the lower end of the manifold 209, is installed at an upper surface of the shutter 219s. The opening/closing operation (elevation operation, rotation operation, and the like) of the shutter 219s is controlled by a shutter opening/closing mechanism 115s.

### (Substrate Support)

As illustrated in FIG. 1, the boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. As such, the boat 217 is configured to arrange the wafers 200 to be spaced apart from each other. The boat 217 is made of a heat resistant material such as quartz or SiC. Heat insulating plates 218 made of a heat resistant material such as quartz or SiC are supported in multiple stages below the boat 217.

As illustrated in FIG. 2, a temperature sensor 263 serving as a temperature detector is installed in the reaction tube 203. Based on temperature information detected by the temperature sensor 263, a state of supplying electric power to the heater 207 is regulated such that the interior of the process chamber 201 has a desired temperature distribution. The temperature sensor 263 is installed along the inner wall of the reaction tube 203 in the same manner as the nozzles 249a and 249b.

### (Control Device)

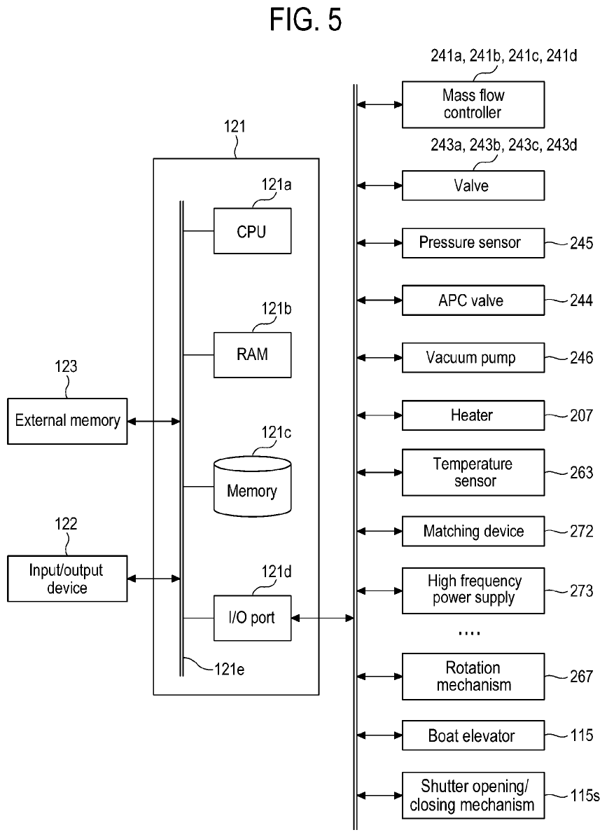

Next, a control device will be described with reference to FIG. 5. As illustrated in FIG. 5, a controller 121, which is a control part (control device), may be configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, for example, a touch panel or the like, is connected to the controller 121.

The memory 121c includes, for example, a flash memory, a hard disk drive (HDD), and the like. A control program that controls operations of a substrate processing apparatus, a process recipe, in which sequences and conditions of a film-forming process to be described below are written, and the like are readably stored in the memory 121c. The process recipe functions as a program configured to cause the controller 121 to execute each sequence in various types of processes (film-forming processes) to be described below, to obtain an expected result. Hereinafter, the process recipe and the control program may be generally and simply referred to as a “program.” Further, the process recipe may be simply referred to as a “recipe.” When the term “program” is used herein, it may indicate a case of including the recipe only, a case of including the control program only, or a case of including both the recipe and the control program. The RAM 121b is configured as a memory area (work area) in which a program or data read by the CPU 121a is temporarily stored.

The I/O port 121d is connected to the MFCs 241a to 241d, the valves 243a to 243d, the pressure sensor 245, the APC valve 244, the vacuum pump 246, the heater 207, the temperature sensor 263, the matching device 272, the high frequency power supply 273, the rotation mechanism 267, the boat elevator 115, the shutter opening/closing mechanism 115s, and the like.

The CPU 121a is configured to read and execute the control program from the memory 121c. The CPU 121a also reads the recipe from the memory 121c according to an input of an operation command from the input/output device 122. The CPU 121a is configured to control the rotation mechanism 267, the flow rate regulating operation of various types of gases by the MFCs 241a to 241d, the opening/closing operation of the valves 243a to 243d, the regulating operation of the high frequency power supply 273 based on impedance monitoring, the opening/closing operation of the APC valve 244, the pressure regulating operation performed by the APC valve 244 based on the pressure sensor 245, the actuating and stopping of the vacuum pump 246, the temperature regulating operation performed by the heater 207 based on the temperature sensor 263, the forward/backward rotation, rotation angle and rotation speed adjustment operation of the boat 217 by the rotation mechanism 267, the operation of moving the boat 217 up or down by the boat elevator 115, and the like, according to contents of the read recipe.

The controller 121 may be configured by installing, on the computer, the aforementioned program stored in an external memory 123 (for example, a magnetic disk such as a HDD, an optical disc such as a CD, a magneto-optical disc such as a MO, or a semiconductor memory such as a USB memory). The memory 121c and the external memory 123 are configured as a computer-readable recording medium. Hereinafter, the memory 121c and the external memory 123 may be generally and simply referred to as a “recording medium.” When the term “recording medium” is used herein, it may indicate a case of including the memory 121c only, a case of including the external memory 123 only, or a case of including both the memory 121c and the external memory 123. Further, the program may be provided to the computer by using communication means such as the Internet or a dedicated line, instead of using the external memory 123.

### (2) Substrate Processing Process

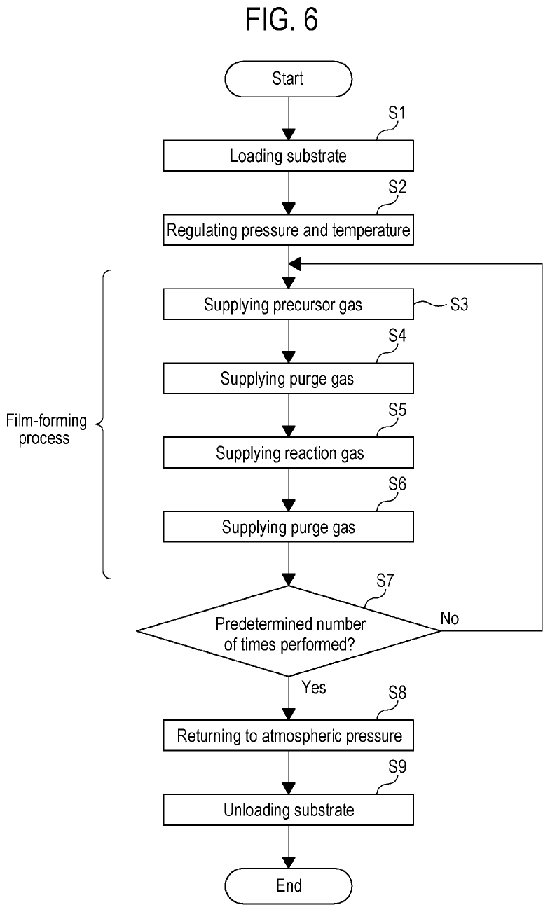

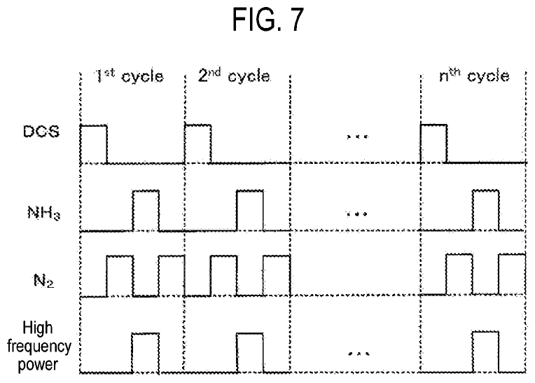

Next, as a process of manufacturing a semiconductor device, a process of forming a thin film on a wafer 200 by using a substrate processing apparatus will be described with reference to FIGS. 6 and 7. In the following descriptions, operations of various parts constituting the substrate processing apparatus are controlled by the controller 121.

Here, an example will be described in which a silicon nitride film (SiN film) is formed, as a film containing Si and N, on a wafer 200 by, non-simultaneously, that is, without being synchronized, a predetermined number of times (one or more times), performing a step of supplying a DCS gas as a precursor gas and a step of supplying a plasma-excited NH₃ gas as a reaction gas. For example, a predetermined film may be formed in advance on the wafer 200. A predetermined pattern may be formed in advance on the wafer 200 or the predetermined film.

In the present disclosure, for the sake of convenience, the film-forming process flow illustrated in FIG. 7 may be denoted as follows. The same notation will be used in description of modifications and other embodiments to be described below.

(DCS→NH₃*)×n⇒SiN

When the term “wafer” is used in the present disclosure, it may refer to “a wafer itself” or “a wafer and a laminated body of certain layers or films formed on a surface of the wafer”. When the phrase “a surface of a wafer” is used in the present disclosure, it may refer to “a surface of a wafer itself” or “a surface of a certain layer formed on a wafer”. When the expression “a certain layer is formed on a wafer” is used in the present disclosure, it may mean that “a certain layer is formed directly on a surface of a wafer itself” or that “a certain layer is formed on a layer formed on a wafer”. When the term “substrate” is used in the present disclosure, it may be synonymous with the term “wafer.”

### (Loading Step: S1)

When a plurality of wafers 200 is charged on the boat 217 (wafer charging), the shutter 219s is moved by the shutter opening/closing mechanism 115s and the lower end opening of the manifold 209 is opened (shutter open). Thereafter, as illustrated in FIG. 1, the boat 217 supporting the plurality of wafers 200 is lifted up by the boat elevator 115 to be loaded into the process chamber 201 (boat loading). In this state, the seal cap 219 seals the lower end of the manifold 209 via the O-ring 220b.

### (Pressure and Temperature Regulating Step: S2)

The interior of the process chamber 201, that is, the space in which the wafers 200 are placed, is vacuum-exhausted (depressurization-exhausted) by the vacuum pump 246 to reach a desired pressure (degree of vacuum). In this operation, the internal pressure of the process chamber 201 is measured by the pressure sensor 245. The APC valve 244 is feedback-controlled based on the measured pressure information. The vacuum pump 246 keeps operating at least until a film-forming step to be described below is completed.

In addition, the wafers 200 in the process chamber 201 are heated by the heater 207 to a desired temperature. In this operation, the state of supplying electric power to the heater 207 is feedback-controlled based on the temperature information detected by the temperature sensor 263 such that the interior of the process chamber 201 has a desired temperature distribution. The heating of the interior of the process chamber 201 by the heater 207 is continuously performed at least until the film-forming step to be described below is completed. However, when the film-forming step is performed under temperature condition of equal to or lower than room temperature, the heating of the interior of the process chamber 201 by the heater 207 may not be performed. In the case where only the process at such a temperature is performed, the heater 207 may not be used, whereby the heater 207 may not be installed in the substrate processing apparatus. This may simplify the configuration of the substrate processing apparatus.

Subsequently, rotation of the boat 217 and the wafer 200 by the rotation mechanism 267 is started. The rotation of the boat 217 and the wafer 200 by the rotation mechanism 267 is continuously performed at least until the film-forming step is completed.

### (Film-Forming Step: S3, S4, S5, and S6)

Then, steps S3, S4, S5, and S6 are sequentially executed to perform a film-forming step.

### (Precursor Gas Supplying Step: S3)

At the step S3, a DCS gas is supplied to the wafer 200 in the process chamber 201.

The valve 243a is opened to allow the DCS gas to flow through the gas supply pipe 232a. A flow rate of the DCS gas is regulated by the MFC 241a, and the DCS gas is supplied from the first ejection holes 250a and the second ejection holes 250b into the process chamber 201 via the nozzle 249a and is exhausted through the exhaust pipe 231. At the same time, the valve 243c is opened to allow a N₂ gas to flow through the gas supply pipe 232c. A flow rate of the N₂ gas is regulated by the MFC 241c, and the N₂ gas is supplied into the process chamber 201 together with the DCS gas and is exhausted through the exhaust pipe 231.

In addition, the valves 243d is opened to allow a N₂ gas to flow through the gas supply pipe 232d to prevent the DCS gas from infiltrating into the nozzle 249b. The N₂ gas is supplied into the process chamber 201 via the gas supply pipe 232b and the nozzle 249b and is exhausted through the exhaust pipe 231.

A supply flow rate of the DCS gas, which is controlled by the MFC 241a, is set to fall within a range of, for example, 1 to 6,000 sccm, specifically 2,000 to 3,000 sccm in some embodiments. A supply flow rate of the N₂ gas, which is controlled by the MFCs 241c and 241d, are set to fall within a range of, for example, 100 to 10,000 sccm. The internal pressure of the process chamber 201 is set to fall within a range of, for example, 1 to 2,666 Pa, specifically 665 to 1,333 Pa in some embodiments. A supply time for the DCS gas is set to a range of, for example, 1 to 10 seconds, specifically 1 to 3 seconds in some embodiments. Further, a supply time for the N₂ gas is set to a range of, for example, 1 to 10 seconds, specifically 1 to 3 seconds in some embodiments.

The temperature of the heater 207 is set such that the temperature of the wafer 200 falls within a range of, for example, 0 to 700 degrees C., specifically room temperature (25 degrees C.) to 550 degrees C., more specifically 40 to 500 degrees C. in some embodiments. As in the embodiments, an amount of heat applied to the wafer 200 can be reduced by setting the temperature of the wafer 200 to 700 degrees C. or less, specifically 550 degrees C. or less, and more specifically 500 degrees C. or less, whereby a heat history suffered by the wafer 200 may be controlled appropriately.

By supplying the DCS gas to the wafer 200 under the aforementioned conditions, a Si-containing layer is formed on the wafer 200 (surface base film). The Si-containing layer may include Cl or H, in addition to a Si layer. The Si-containing layer is formed on the outermost surface of the wafer 200 when DCS is physically adsorbed, a substance obtained by partial decomposition of DCS is chemically adsorbed, or Si is deposited by thermal decomposition of DCS. That is, the Si-containing layer may be an adsorption layer (physical adsorption layer or chemical adsorption layer) of DCS or a substance obtained by partial decomposition of DCS, or a Si deposition layer (Si layer).

After the Si-containing layer is formed, the valve 243a is closed to stop the supply of the DCS gas into the process chamber 201. At this time, with the APC valve 244 kept open, the interior of the process chamber 201 is vacuum-exhausted by the vacuum pump 246 to remove the unreacted DCS gas, the DCS gas having contributed to the formation of the Si-containing layer, or reaction by-products remaining in the process chamber 201 from the process chamber 201.

### (Purge Gas Supplying Step: S4)

Further, at this time, the supply of the N₂ gas into the process chamber 201 is maintained while the valves 243c and 243d remain open. The N₂ gas acts as a purge gas. Since the nozzle 249a connected to the valve 243c includes the first ejection holes 250a and the second ejection holes 250b, the purge gas is supplied (ejected) not only to the wafer 200 supported by the boat 217 but also to the inner wall of the reaction tube 203 (S4). A supply flow rate of the N₂ gas controlled by the MFC 241c at this time is set to fall within a range of, for example, 1,000 to 5,000 sccm. At this time, a supply flow rate of the N₂ gas supplied by the first ejection holes 250a of the nozzle 249a is set to fall within a range of, for example, 900 to 4,500 sccm. Further, a supply flow rate of the N₂ gas supplied by the second ejection holes 250b of the nozzle 249a is set to fall within a range of, for example, 100 to 500 sccm. The relationship between the supply flow rates of the N₂ gas from the first ejection holes 250a and the second ejection holes 250b may be regulated by the number of installation and the opening diameters of the first ejection holes 250a and second ejection holes 250b. For example, in a case where the number of installation of the first ejection holes 250a and the second ejection holes 250b has a ratio of 2.5:1 and the opening diameters of the first ejection holes 250a and second ejection holes 250b have a ratio of 2:1, the supply flow rate of the N₂ gas may be set to have the above-mentioned relationship.

That is, here, the N₂ gas (inert gas) as the purge gas is supplied from the first ejection holes 250a to the wafer 200 and is supplied from the second ejection holes 250b to the inner wall of the reaction tube 203. This step is performed after stop of the supply of the DCS gas as the precursor gas and before start of the supply of the reaction gas to be described below, that is, between the precursor gas supplying step and the reaction gas supplying step. At this time, the flow rate of the N₂ gas supplied from the first ejection holes 250a is larger than the flow rate of the N₂ gas supplied from the second ejection holes 250b, as described above.

As the precursor gas, in addition to the DCS gas, it may be possible to appropriately use, for example, various aminosilane precursor gases such as a tetrakisdimethylaminosilane (Si[N(CH₃)₂]₄, abbreviation: 4DMAS) gas, a trisdimethylaminosilane (Si[N(CH₃)₂]₃H, abbreviation: 3DMAS) gas, a bisdimethylaminosilane (Si[N(CH₃)₂]₂H₂, abbreviation: BDMAS) gas, a bisdiethylaminosilane (Si[N(C₂H₅)₂]₂H₂, abbreviation: BDEAS) gas, a bistertiarybutylaminosilane (SiH₂[NH(C₄H₉)]₂, abbreviation: BTBAS) gas, a dimethylaminosilane (DMAS) gas, a diethylaminosilane (DEAS) gas, a dipropylaminosilane (DPAS) gas, a diisopropylaminosilane (DIPAS) gas, a butylaminosilane (BAS) gas, a hexamethyldisilazane (HMDS) gas, and the like, inorganic halosilane precursor gases such as a monochlorosilane (SiH₃Cl, abbreviation: MCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, an octachlorotrisilane (Si₃Cl₈, abbreviation: OCTS) gas, and the like, and halogen group-free inorganic silane precursor gases such as a monosilane (SiH₄, abbreviation: MS) gas, a disilane (Si₂H₆, abbreviation: DS) gas, a trisilane (Si₃H₈, abbreviation: TS) gas, and the like.

Examples of the inert gas may include rare gases such as an Ar gas, a He gas, a Ne gas, a Xe gas, and the like, in addition to the N₂ gas.

### (Reaction Gas Supplying Step: S5)

After the precursor gas supplying step is completed, a plasma-excited NH₃ gas as a reaction gas is supplied to the wafer 200 in the process chamber 201 (S5).

In this step, the opening/closing control of the valves 243b to 243d is performed in the same procedure as the opening/closing control of the valves 243a, 243c, and 243d in the step S3. A flow rate of the NH₃ gas is regulated by the MFC 241b, and the NH₃ gas is supplied into the buffer chamber 237 via the nozzle 249b. At this time, high frequency power is supplied among the rod-shaped electrodes 269, 270, and 271. The NH₃ gas supplied into the buffer chamber 237 is excited into a plasma state (converted into plasma and activated), supplied as active species (NH₃*) into the process chamber 201, and exhausted via the exhaust pipe 231.

The supply flow rate of the NH₃ gas, which is controlled by the MFC 241b, is set to fall within a range of, for example, 100 to 10,000 sccm, specifically 1,000 to 2,000 sccm in some embodiments. The high frequency power applied to the rod-shaped electrodes 269, 270, and 271 is set to fall within a range of, for example, 50 to 600 W. The internal pressure of the process chamber 201 is set to fall within a range of, for example, 1 to 500 Pa. By using plasma, the NH₃ gas can be activated even when the internal pressure of the process chamber 201 is set to such a relatively low pressure zone. The time during which the active species obtained by plasma-excitation of the NH₃ gas is supplied to the wafer 200, that is, the gas supply time (irradiation time), is set to fall within a range of, for example, 1 to 180 seconds, specifically 1 to 60 seconds in some embodiments. Other process conditions are the same as those in the step S3 described above.

By supplying the NH₃ gas to the wafer 200 under the aforementioned conditions, the Si-containing layer formed on the wafer 200 is plasma-nitrided. At this time, the Si—Cl bond and Si—H bond of the Si-containing layer are cut by an energy of the plasma-excited NH₃ gas. Cl and H de-bonded from Si are desorbed from the Si-containing layer. Then, Si in the Si-containing layer, which has a dangling bond due to desorption of Cl or the like, is bonded to N contained in the NH₃ gas to form a Si—N bond. As this reaction proceeds, the Si-containing layer can be changed (modified) into a layer containing Si and N, that is, a silicon nitride layer (SiN layer).

The NH₃ gas may be plasma-excited and then supplied to modify the Si-containing layer into the SiN layer. This is because, even when the NH₃ gas is supplied in a non-plasma atmosphere, an energy to nitride the Si-containing layer is insufficient in the above-mentioned temperature zone, and accordingly, it is difficult to increase the Si—N bond by sufficiently desorbing Cl and H from the Si-containing layer or sufficiently nitriding the Si-containing layer.

After the Si-containing layer is changed into the SiN layer, the valve 243b is closed to stop the supply of the NH₃ gas. Further, the supply of the high frequency power among the rod-shaped electrodes 269, 270, and 271 is stopped. Then, the NH₃ gas and reaction by-products remaining in the process chamber 201 are removed from the process chamber 201 according to the same processing procedure and process conditions as in the step S4.

### (Purge Gas Supplying Step: S6)

Then, also at this time, as in the case of the step S4, a N₂ gas (inert gas) as a purge gas is supplied from the first ejection holes 250a to the wafer 200 and is supplied from the second ejection holes 250b to the inner wall of the reaction tube 203. This step is performed after the supply of the plasma-excited NH₃ gas as the reaction gas is stopped, that is, after the step of supplying the reaction gas is performed. At this time, the flow rate of the N₂ gas supplied from the first ejection holes 250a is larger than the flow rate of the N₂ gas supplied from the second ejection holes 250b, as described above.

As a nitriding agent, that is, a NH₃-containing gas to be plasma-excited, in addition to the NH₃ gas, it may be possible to use, for example, a diazene (N₂H₂) gas, a hydrazine (N₂H₄) gas, a N₃H₈ gas, or the like.

As an inert gas, for example, various rare gases exemplified in the step S4 may be used in addition to the N₂ gas.

### (Performing Predetermined Number of Times: S7)

A cycle that non-simultaneously, that is, asynchronously, performs the steps S3, S4, S5, and S6 is performed in this order a predetermined number of times (n times), that is, one or more times (S7), to thereby form a SiN film having a predetermined composition and a predetermined film thickness on the wafer 200. The aforementioned cycle may be performed multiple times. That is, a thickness of the SiN layer formed per one cycle may be set to be smaller than a desired film thickness. Thus, the aforementioned cycle may be performed multiple times until a film thickness of the SiN film formed by laminating the SiN layers becomes equal to the desired film thickness in some embodiments.

After the predetermined number of times (n times) of cycles (see “n^{th} cycle” in FIG. 7) is completed, the opening/closing control of the valve 243c may be then performed to eject a N₂ gas (inert gas) as a purge gas from each of the first ejection holes 250a and the second ejection holes 250b in the nozzle 249a for a predetermined time. In that case, it is possible to shorten at least one selected from the group of the time during which the N₂ gas is supplied in the step S4 and the time during which the N₂ gas is supplied in the step S6, as compared with a case where there is no supply of the inert gas after completion of the cycle.

### (Returning to Atmospheric Pressure Step: S8)

After the aforementioned film-forming process is completed, a N₂ gas as an inert gas is supplied into the process chamber 201 from each of the gas supply pipes 232c and 232d and is exhausted via the exhaust pipe 231. Thus, the interior of the process chamber 201 is purged with the inert gas to remove a gas and the like remaining in the process chamber 201 from the interior of the process chamber 201 (inert gas purge). The internal atmosphere of the process chamber 201 is then substituted with the inert gas (inert gas substitution) and the internal pressure of the process chamber 201 is returned to an atmospheric pressure (S8).

### (Unloading Step: S9)

Then, the seal cap 219 is moved down by the boat elevator 115 to open the lower end of the manifold 209. In addition, the processed wafers 200 supported by the boat 217 are unloaded from the lower end of the manifold 209 to the outside of the reaction tube 203 (boat unloading) (S9). After the boat unloading, the shutter 219s is moved, and the lower end opening of the manifold 209 is sealed by the shutter 219s via the O-ring 220c (shutter closing). After being unloaded from the reaction tube 203, the processed wafers 200 are discharged from the boat 217 (wafer discharging). After the wafer discharging, an empty boat 217 may be loaded into the process chamber 201.

### (3) Effects According to the Embodiments

According to the embodiments, one or more effects set forth below may be achieved.

(a) According to the embodiments, the nozzle 249a includes the first ejection holes 250a and the second ejection holes 250b, and the N₂ gas (inert gas) as the purge gas is supplied (ejected) from the first ejection holes 250a to the wafer 200 and is supplied (ejected) from the second ejection holes 250b to the inner wall of the reaction tube 203. That is, the N₂ gas (inert gas) as the purge gas is supplied (ejected) not only to the wafer 200 but also to the inner wall of the reaction tube 203. Therefore, at the same time when the wafer 200 is purged, the inner wall of the reaction tube 203 is also purged, thereby effectively preventing reaction by-products from adhering to the inner wall of the reaction tube 203. When the generation of deposits on the inner wall of the reaction tube 203 can be suppressed, the generation of foreign substances (particles) caused by the deposits (reaction by-products, and the like) can also be suppressed, thereby avoiding quality deterioration of processing on the wafer 200 in advance.

(b) According to the embodiments, since an installation interval (second predetermined interval) of the second ejection holes 250b is wider than an installation interval (first predetermined interval) of the first ejection holes 250a, the flow rate of the N₂ gas (inert gas) as the purge gas supplied from the first ejection holes 250a is larger than the flow rate of the N₂ gas (inert gas) as the purge gas supplied from the second ejection holes 250b. In other words, the deposits on the inner wall of the reaction tube 203 can be efficiently removed with a flow rate smaller than the flow rate of the purge gas ejected toward the center of the wafer 200. Therefore, even when the wafer 200 and the inner wall of the reaction tube 203 are purged, each purging can be efficiently performed with an appropriate gas flow rate.

(c) According to the embodiments, the first ejection holes 250a and the second ejection holes 250b are formed at positions opposite to each other. Therefore, it is possible to effectively purge a back side of the nozzle 249a when viewed from the wafer 200's side, that is, a portion where a gas collects between the nozzle 249a and the inner wall of the reaction tube 203, which is very useful in preventing the generation of deposits on the inner wall of the reaction tube 203.

### (First Modification)

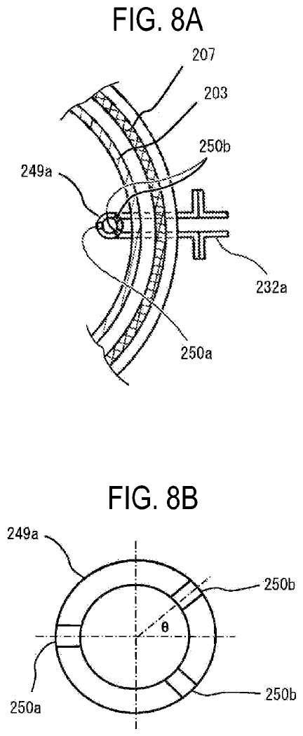

Next, a first modification of the embodiments will be described with reference to FIGS. 8A and 8B. In the first modification, only parts different from the aforementioned embodiments will be described below, and description of the same parts will be omitted.

In the aforementioned embodiments, the nozzle 249a having a configuration in which the second ejection holes 250b are formed at positions opposite to the first ejection holes 250a has been described in detail, but in the present first modification, as the second ejection holes 250b, a plurality of ejection holes having different ejection directions are formed in the nozzle 249a. Therefore, the N₂ gas (inert gas) for the inner wall of the reaction tube 203 is supplied (ejected) from the plurality of second ejection holes 250b having different ejection directions.

In the first modification, the second ejection holes 250b are formed at, for example, two places. In that case, it is assumed that an angle θ formed by the ejection direction of the second ejection holes 250b of each of the two places and the direction along the first ejection holes 250a falls within a range of 45 degrees to 90 degrees (see FIG. 8B). In a case where the angle θ is less than 45 degrees, an effect of purging on the inner wall of the reaction tube 203 is substantially the same as a case where only one second ejection holes 250b is formed (that is, the case of the aforementioned embodiments). Further, in a case where the angle θ exceeds 90 degrees, the efficiency of removing the deposits on the back side of the nozzle 249a may decrease. When the angle θ falls within the range of 45 degrees to 90 degrees, it is possible to efficiently remove the deposits on the inner wall of the reaction tube 203 over a wide range while enabling effective purging on the back side of the nozzle 249a.

As described above, according to the first modification, the N₂ gas (inert gas) as the purge gas is supplied (ejected) from the plurality of second ejection holes 250b having different ejection directions to the inner wall of the reaction tube 203. Therefore, the deposits on the inner wall of the reaction tube 203 can be efficiently removed over a wide range. Further, it is possible to effectively purge the back side of the nozzle 249a, that is, a portion where a gas collects between the nozzle 249a and the inner wall of the reaction tube 203.

### (Second Modification)

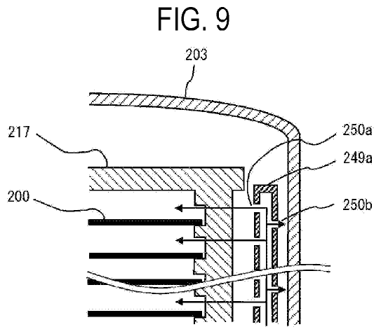

Next, a second modification of the embodiments will be described with reference to FIG. 9. Also in the second modification, only parts different from the aforementioned embodiments will be described below, and description of the same parts will be omitted.

In the second modification, the first ejection holes 250a and the second ejection holes 250b are formed at positions having different heights with respect to the height direction of the nozzle 249a. That is, unlike the case of the aforementioned embodiments (see FIG. 3), none of the second ejection holes 250b is formed at the same height as the first ejection holes 250a.

In this way, according to the second modification, the positions of the first ejection holes 250a and the second ejection holes 250b are different from each other in the height direction of the nozzle 249a. Therefore, it may be easier to control the flow rate of the purge gas supplied (ejected) from the first ejection holes 250a and the second ejection holes 250b, as compared with the case of the basic configuration in the aforementioned embodiments (see FIG. 3). That is, it may be suitable for efficiently purging the wafer 200 and the inner wall of the reaction tube 203 with an appropriate gas flow rate.

### (Third Modification)

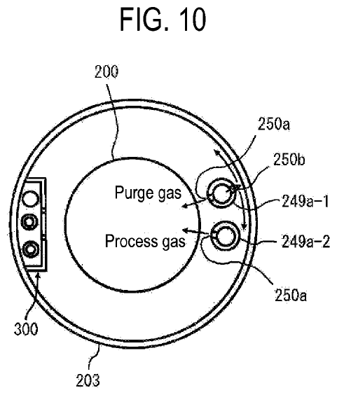

Next, a third modification of the embodiments will be described with reference to FIG. 10. Also in the third modification, only parts different from the aforementioned embodiments will be described below, and description of the same parts will be omitted.

In the third modification, a nozzle 249a-1 configured to supply a N₂ gas (inert gas) as a purge gas and a nozzle 249a-2 configured to supply a DCS gas (precursor gas) as a process gas are arranged in the reaction tube 203, as separate bodies. That is, unlike the case of the aforementioned embodiments in which the nozzle 249a is shared in supplying the process gas and supplying the purge gas (see FIGS. 1 and 2), the nozzle 249a-1 configured to supply the purge gas is installed in the reaction tube 203, separately from the nozzle 249a-2 configured to supply the process gas (however, an inert gas as a carrier gas may be supplied together).

The first ejection holes 250a and the second ejection holes 250b are formed in the nozzle 249a-1 configured to supply the purge gas. The second ejection holes 250b are arranged at a positions opposite to the first ejection holes 250a. However, as in the aforementioned first modification, the second ejection holes 250b may be arranged at a plurality of locations having different ejection directions. Further, as in the aforementioned second modification, the first ejection holes 250a and the second ejection holes 250b may be arranged at positions having different heights with respect to the height direction of the nozzle 249a-1.

According to the third modification having such a configuration, since the nozzle 249a-1 have the first ejection holes 250a and the second ejection holes 250b, the N₂ gas (inert gas) as the purge gas is supplied (ejected) not only to the wafer 200 but also to the inner wall of the reaction tube 203. Therefore, at the same time when purging the wafer 200, the inner wall of the reaction tube 203 is also purged, thereby effectively preventing reaction by-products from adhering to the inner wall of the reaction tube 203.

Further, according to the third modification, since the nozzle 249a-1 configured to supply the purge gas is installed separately from the nozzle 249a-2 configured to supply the process gas, a versatility of control of supplying the purge gas may be improved and control contents may be optimized, as compared with the case of the aforementioned embodiments (that is, the case where the nozzle is shared).

### OTHER EMBODIMENTS OF THE PRESENT DISCLOSURE

Some embodiments of the present disclosure have been described in detail above. However, the present disclosure is not limited to the aforementioned embodiments but may be variously modified without departing from the gist of the present disclosure.

For example, examples in which the reaction gas is supplied after the precursor gas is supplied have been described in the above-described embodiments. However, the present disclosure is not limited to such embodiments, but a supply order of the precursor gas and the reaction gas may be reversed. That is, the precursor gas may be supplied after the reaction gas is supplied. By changing the supply order, a film quality and a composition ratio of a film to be may be changed.

Further, configuration examples including the plasma generation part that excites (activates) the reaction gas into the plasma state have been described in the aforementioned embodiments. However, the present disclosure is not limited to such embodiments but may also be applied to a substrate processing apparatus with no plasma generation part. That is, the plasma generation part (buffer chamber) may be included, and even in a case where a substrate processing apparatus does not include the plasma generation part, the present disclosure may be applied to the substrate processing apparatus as long as the substrate processing apparatus includes a dedicated nozzle configured to supply a purge gas.

Further, examples in which the SiN film is formed on the wafer 200 have been described in the aforementioned embodiments and the like. The present disclosure is not limited to such embodiments but may be suitably applied to a case of forming a Si-based oxide film such as a silicon oxide film (SiO film), a silicon oxycarbide film (SiOC film), a silicon oxycarbonitride film (SiOCN film), and a silicon oxynitride film (SiON film) on the wafer 200, and a case of forming a Si-based nitride film such as a silicon carbonitride film (SiCN film), a silicon boronitride film (SiBN film), a silicon borocarbonitride film (SiBCN film), and a borocarbonitride film (BCN film) on the wafer 200. In these cases, in addition to the O-containing gas, a C-containing gas such as C₃H₆, a N-containing gas such as NH₃, or a B-containing gas such as BCl₃ may be used as the reaction gas.

In addition, the present disclosure may also be suitably applied to a case of forming an oxide film or a nitride film containing a metal element such as titanium (Ti), zirconium (Zr), hafnium (Hf), tantalum (Ta), niobium (Nb), aluminum (Al), molybdenum (Mo), and tungsten (W), that is, a metal-based oxide film or a metal-based nitride film, on the wafer 200. That is, the present disclosure may also be suitably applied to a case of forming a TiO film, a TiN film, a TiOC film, a TiOCN film, a TiON film, a TiBN film, a TiBCN film, a ZrO film, a ZrN film, a ZrOC film, a ZrOCN film, a ZrON film, a ZrBN film, a ZrBCN film, a HfO film, a HfN film, a HfOC film, a HfOCN film, a HfON film, a HfBN film, a HfBCN film, a TaO film, a TaOC film, a TaOCN film, a TaON film, a TaBN film, a TaBCN film, a NbO film, a NbN film, a NbOC film, a NbOCN film, a NbON film, a NbBN film, a NbBCN film, an AlO film, an AlN film, an AlOC film, an AlOCN film, an AlON film, an AlBN film, an AlBCN film, a MoO film, a MoN film, a MoOC film, a MoOCN film, a MoON film, a MoBN film, a MoBCN film, a WO film, a WN film, a WOC film, a WOCN film, a WON film, a MWBN film, a WBCN film, or the like on the wafer 200.

In these cases, as the precursor gas, it may be possible to use, for example, a tetrakis(dimethylamino)titanium (Ti[N(CH₃)₂]₄, abbreviation: TDMAT) gas, a tetrakis(ethylmethylamino)hafnium (Hf[N(C₂H₅)(CH₃)]₄, abbreviation: TEMAH) gas, a tetrakis(ethylmethylamino)zirconium (Zr[N(C₂H₅)(CH₃)]₄, abbreviation: TEMAZ) gas, a trimethylaluminum (Al(CH₃)₃, abbreviation: TMA) gas, a titaniumtetrachloride (TiCl₄) gas, a hafniumtetrachloride (HfCl₄) gas, or the like. As the reaction gas, the aforementioned reaction gas may be used.

That is, the present disclosure can be suitably applied to a case of forming a half metal-based film containing a half metal element or a metal-based film containing a metal element. The processing procedures and process conditions of this film-forming process may be the same as those of the film-forming processes described in the aforementioned embodiments and modifications. Even in this case, the same effects as those of the aforementioned embodiments and modifications can be obtained.

Recipes used in the film-forming process may be provided individually according to the processing contents and may be stored in the memory 121c via a telecommunication line or the external memory 123 in some embodiments. Moreover, at the beginning of various types of processes, the CPU 121a may properly select an appropriate recipe from the recipes stored in the memory 121c according to the contents of the processing in some embodiments. Thus, it is possible for a single substrate processing apparatus to form films of various types, composition ratios, qualities, and thicknesses for general purpose and with enhanced reproducibility. In addition, it is possible to reduce an operator's burden and to quickly start the various types of processes while avoiding an operation error.

The recipes mentioned above are not limited to newly-provided ones but may be provided, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the substrate processing apparatus may be directly modified by operating the input/output device 122 of the substrate processing apparatus.

According to some embodiments of the present disclosure, it is possible to provide a technique capable of preventing generation of deposits on an inner wall of a reaction tube.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a substrate support configured to support at least one substrate;
a reaction tube configured to accommodate the substrate support and process the at least one substrate; and
an inert gas supply system configured to supply an inert gas into the reaction tube,
wherein the inert gas supply system includes a nozzle including at least one first ejection hole configured to eject the inert gas toward a center of the at least one substrate and at least one second ejection hole configured to eject the inert gas toward an inner wall of the reaction tube.

2. The substrate processing apparatus of claim 1, wherein the at least one first ejection hole and the at least one second ejection hole are formed at positions opposite to each other.

3. The substrate processing apparatus of claim 1, wherein the at least one second ejection hole is formed at the same height as the at least one first ejection hole with respect to a height direction of the nozzle.

4. The substrate processing apparatus of claim 1, wherein the at least one first ejection hole and the at least one second ejection hole are formed at positions different from each other in height with respect to a height direction of the nozzle.

5. The substrate processing apparatus of claim 1, wherein the at least one second ejection hole includes a plurality of second ejection holes, and
wherein the plurality of second ejection holes have different ejection directions.

6. The substrate processing apparatus of claim 5, wherein angles of the different ejection directions of the plurality of second ejection holes fall within a range of 45 to 90 degrees.

7. The substrate processing apparatus of claim 1, wherein the at least one first ejection hole includes a plurality of first ejection holes, and the at least one second ejection hole includes a plurality of second ejection holes,
wherein the plurality of first ejection holes are formed at first predetermined intervals with respect to a height direction of the nozzle, and
wherein the plurality of second ejection holes are formed at second predetermined intervals, each of which is wider than each of the first predetermined intervals, with respect to the height direction of the nozzle.

8. The substrate processing apparatus of claim 1, wherein the at least one first ejection hole includes a plurality of first ejection holes, and
wherein each of the at least one second ejection hole is formed between two of the plurality of first ejection holes with respect to a height direction of the nozzle.

9. The substrate processing apparatus of claim 1, wherein the at least one substrate includes a plurality of substrates, and the at least one first ejection hole includes a plurality of first ejection holes,
wherein the substrate support is further configured to hold the plurality of substrates in multiple stages in a vertical direction, and
wherein the plurality of first ejection holes are formed to eject the inert gas to each of the plurality of substrates.

10. The substrate processing apparatus of claim 1, wherein the at least one first ejection hole includes a plurality of first ejection holes and the at least one second ejection hole includes a plurality of second ejection holes,
wherein the plurality of first ejection holes and the plurality of second ejection holes are formed in the nozzle from a lower portion to an upper portion of the reaction tube respectively, and
wherein the number of the plurality of first ejection holes is larger than the number of the plurality of second ejection holes.

11. The substrate processing apparatus of claim 1, wherein an opening diameter of the at least one first ejection hole is larger than an opening diameter of the at least one second ejection hole.

12. The substrate processing apparatus of claim 1, wherein shapes of openings of the at least one first ejection hole and the at least one second ejection hole are circular or elliptical.

13. A method of manufacturing a semiconductor device, comprising:
loading a substrate into a reaction tube;
supplying a process gas into the reaction tube;
supplying an inert gas from a first ejection hole of a nozzle to the substrate and supplying the inert gas from at least one second ejection hole of the nozzle to an inner wall of the reaction tube, the nozzle including the first ejection hole configured to eject the inert gas toward a center of the substrate and the at least one second ejection hole configured to eject the inert gas toward the inner wall of the reaction tube; and
unloading the substrate from the reaction tube.

14. The method of claim 13, wherein the act of supplying the process gas includes:
supplying a precursor gas into the reaction tube; and
supplying a reaction gas into the reaction tube, and
wherein the act of supplying the inert gas is performed between the act of supplying the precursor gas and the act of supplying the reaction gas, and performed after the act of supplying the reaction gas.

15. The method of claim 13, wherein in the act of supplying the inert gas, a flow rate of the inert gas supplied from the first ejection hole is made larger than a flow rate of the inert gas supplied from the at least one second ejection hole.

16. The method of claim 13, wherein the at least one second ejection hole includes a plurality of second ejection holes having different ejection directions, and
wherein in the act of supplying the inert gas, the inert gas is supplied from the plurality of second ejection holes to the inner wall of the reaction tube.

17. A non-transitory computer-readable recording medium storing a program that causes, by a computer, a substrate processing apparatus to perform a process comprising:
loading a substrate into a reaction tube of the substrate processing apparatus;
supplying a process gas into the reaction tube;
supplying an inert gas from a first ejection hole of a nozzle to the substrate and supplying the inert gas from at least one second ejection hole of the nozzle to an inner wall of the reaction tube, the nozzle including the first ejection hole configured to eject the inert gas toward a center of the substrate and the at least one second ejection hole configured to eject the inert gas toward the inner wall of the reaction tube; and
unloading the substrate from the reaction tube.

18. The non-transitory computer-readable recording medium of claim 17, wherein the act of supplying the process gas includes:
supplying a precursor gas into the reaction tube; and
supplying a reaction gas into the reaction tube, and
wherein the act of supplying the inert gas is performed between the act of supplying the precursor gas and the act of supplying the reaction gas, and performed after the act of supplying the reaction gas.

19. The non-transitory computer-readable recording medium of claim 17, wherein in the act of supplying the inert gas, a flow rate of the inert gas supplied from the first ejection hole is made larger than a flow rate of the inert gas supplied from the at least one second ejection hole.

20. The non-transitory computer-readable recording medium of claim 17, wherein the at least one second ejection hole includes a plurality of second ejection holes having different ejection directions, and
wherein in the act of supplying the inert gas, the inert gas is supplied from the plurality of second ejection holes to the inner wall of the reaction tube.
